(19) United States
(12) Patent Application Publication
(10) Pub. No.: US 2007/0291572 A1
(43) Pub. Date: Dec. 20, 2007

(54) Clock circuit for semiconductor memory

(76) Inventors: Josef Schnell, Charlotte, VT (US); Farrukh Aquil, South Burlington, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/471,391

(22) Filed: Jun. 20, 2006

(51) Int. Cl. G11C 8/00

(52) U.S. Cl. 365/230.03

(57) ABSTRACT

A memory component includes at least one memory bank array, a first and a second region, a clock tree, and a clock control circuit. The memory component is configured in a semiconductor wafer. The at least one memory bank array is configured such that data is read out of it during a read operation. The clock tree is coupled between the first and second regions and is configured for driving data during the read operation. The clock control circuit is configured within one of the first and second regions and is responsive to read control signals in order to prevent driving the clock tree outside of the read operation.

### BACKGROUND

In many present day DRAM applications or in systems incorporating a DRAM, the total amount of power consumed by the application, including by the DRAM, is a significant consideration. For example, power consumption can be significant in the market driven by mobile applications. Power is consumed by DRAM is attributable to a number of system operations including its refresh operations, its read operations, and its write operations, among others. Given continuing demand for overall lower power consumption, decreasing power consumed in any of these operations is significant. For this and other reasons, a need exists for the present invention.

### SUMMARY

One embodiment of the present invention provides a memory component. The memory component includes at least one memory bank array, a first and a second region, a clock tree, and a clock control circuit. The memory component is configured in a semiconductor wafer. The at least one memory bank array is configured such that data is read out of it during a read operation. The clock tree is coupled between the first and second regions and is configured for driving data during the read operation. The clock control circuit is configured within one of the first and second regions and is responsive to read control signals in order to prevent driving the clock tree outside of the read operation.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating a memory device including a clock control circuit in accordance with one embodiment of the present invention.

FIG. 2 is a block diagram illustrating a clock control circuit in accordance with one embodiment of the present invention.

FIG. 3 is a timing diagram illustrating exemplary timing signals for one embodiment of a circuit for a random access memory including a clock control circuit in accordance with one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

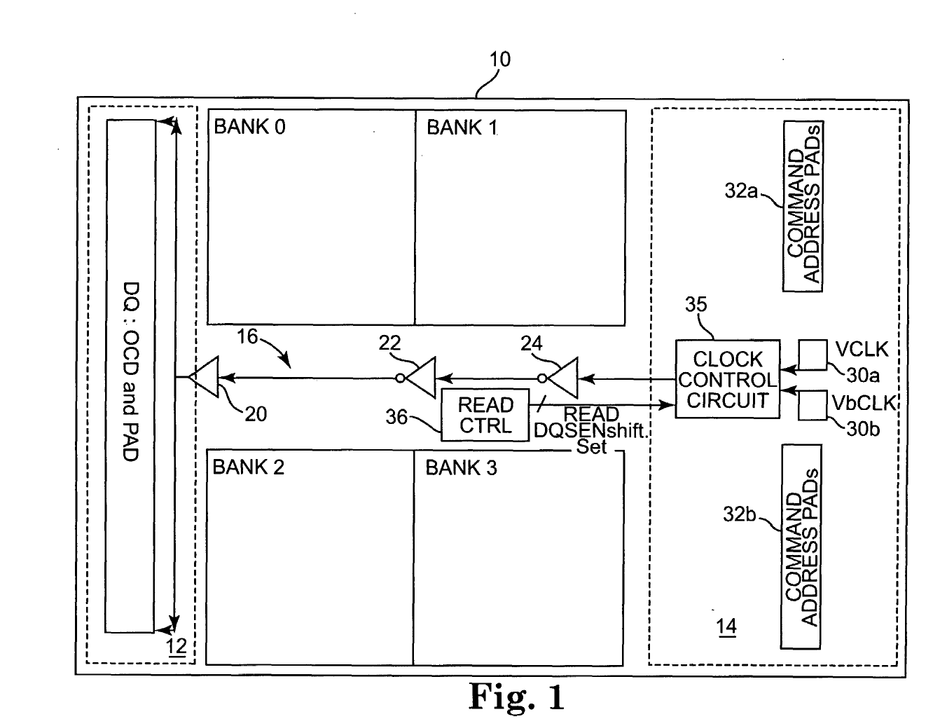

FIG. 1 illustrates a memory device 10 with an edge pad arrangement and multiple memory banks. In one embodiment, memory device 10 includes four memory bank arrays: bank 0, bank 1, bank 2, and bank 3. Memory device 10 further includes first region 12, second region 14 and clock tree 16 coupled between them. Access to the four memory banks is provided by a data path coupled between the memory banks and first and second regions 12 and 14, via which data is read from bank 0, bank 1, bank 2, and/or bank 3.

In one embodiment memory device 10 is a low power DRAM chip, such as a low power DDR SDRAM. Bank 0, bank 1, bank 2, and bank 3 are organized in a square or rectangular-shaped configuration on the semiconductor memory device 10. In some cases, data pads and command and address pads are then physically located adjacent the edge of the semiconductor chip (as illustrated in FIG. 1) and in other applications they are situated between the memory banks on the chip. In various embodiments, data pads can be configured to accommodate 16-bit, 32-bit or other system architecture.

In one embodiment, first region 12 includes data pads (“DQ pads”) and off-chip drivers (“OCD”) 31, and second region 14 includes command and address pads 32a/32b, clock pads 30a and 30b. The DQ pads and OCD 31, the command and address pads 32a/32b, and the clock pads 30a and 30b are each coupled to buffer and multiplexing logic and the data path.

In operation, command and address pads 32a/32b receive command and address signals for retrieving data from the various memory banks (bank0, bank 1, bank 2, and bank 3) in memory device 10. Data is then retrieved from the various memory banks via DQ pads 31 in first region 12. DQ pads 31 are coupled to paths that allow data to be transmitted off memory device 10. Clock pads 30a and 30b in second region 14 are configured to receive differential clock signals VCLK and VbCLK from off memory device 10, such as from a memory controller or other device coupled to memory device 10. These clock signals are then used to drive clock tree 16, which in turn drives the DQ pads and OCD 31 in first region 12.

In one embodiment, clock tree 16 is coupled between first region 12 and second region 14 and it includes buffer 20 and first and second inverters 22 and 24. Metal wires connected between buffer 20 and first and inverter 22 and between first and second inverters 22 and 24 are illustrated with arrows. In some cases, the distance between first region 12 and second region 14 is small, or first and second regions are located in the essentially the same area on memory device 10. In other cases, however, the distance between first region 12 and second region 14 is significant, and thus, requires that clock tree 16 has a significant distance. In such cases, the metal wires between buffer 20 and first and second inverters 22 and 24 also have significant length. As such, power loss can be significant as buffer 20 and inverters 22 and 24 drive the long metal wires of clock tree 16.

In one embodiment, second region 14 further includes clock control circuit 35. In one embodiment, clock control circuit 35 is configured to receive the differential clock signals VCLK and VbCLK and is further configured to regulate these signals. In one embodiment, clock control circuit 35 regulates the VCLK and VbCLK clock signals so that clock tree 16 is activated for the read data only during a read operation. Outside the read operation, clock tree is not driven. Such regulation of clock tree 16 reduces power consumed by memory device 10.

In one embodiment, clock control circuit 35 regulates the VCLK and VbCLK clock signals in accordance with control signals from read control circuit 36, which is also provided on memory device 10. Among other signals, read control circuit 36 generates a READ signal, a DQSENshift signal and a SET signal. These signals from read control circuit 36 are provided to clock control circuit 35, which then uses these signals to control VCLK and VbCLK clock signals in order to decrease power consumption by activating clock tree 16 for the read data only during a read operation.

In one embodiment, memory device 10 is a semiconductor memory chip package, such that DQ pads 31 in first region 12 are located along a first edge of the chip package and such that command and address pads 32a/32b in second region 14 are located along a second edge of the chip package opposite the first edge. In another embodiment, memory device 10 is a semiconductor wafer or die. In that case, DQ pads 31 in first region 12 are located along a first of the semiconductor wafer or die and command and address pads 32a/32b in second region 14 are located along a second edge of the semiconductor wafer or die. In either case, where first and second regions 12 and 14 are separated across the chip or wafer, metal lines with clock tree 16 will have significant length, and thus, significant power loss when driven.

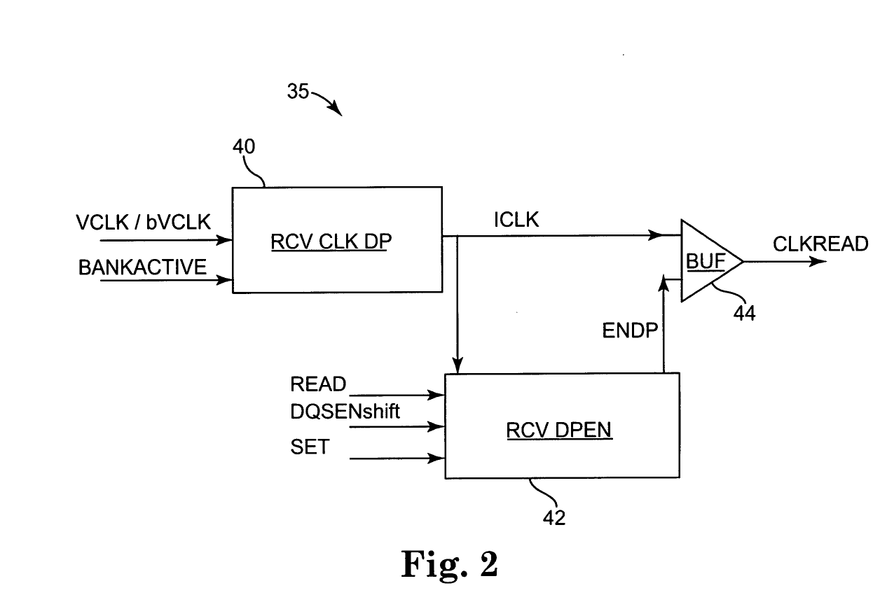

FIG. 2 is a block diagram illustrating further detail of clock control circuit 35 in accordance with one embodiment of the present invention. In one embodiment, clock control circuit 35 includes data clock receiver 40, buffer enable logic 42 and clock buffer 44.

Data clock receiver 40 is configured to receive differential clock signals VCLK and VbCLK as well as a BANKACTIVE signal. As indicated earlier, the VCLK and VbCLK clock signals are differential clock signal received from off the memory chip 10, such as from a memory controller or the like. The BANKACTIVE signal is a signal that transitions each time a memory bank is selected to be accessed. Responsive to these received signals, data clock receiver 40 is further configured to generate an ICLK signal and provide it to both buffer enable logic 42 and to clock buffer 44.

Buffer enable logic 42 is configured to receive the ICLK signal generated by data clock receiver 40, and is further configured to receive a READ signal, a DQSENshift signal, and a SET signal. The READ signal is the read command signal that is internal to memory device 10 that transitions high when a read command is asserted. The DQSENshift signal is the DQ enable signal shifted in time in order to account for latencies and yet still capture data during a read. The SET signal resets buffer enable logic 42 when needed, such as during a power up. The ICLK signal drives buffer enable logic 42 to produce an ENDP enable signal that is then received by clock buffer 44.

Clock buffer 44 receives the ICLK signal from data clock receiver 40 and the ENDP signal from buffer enable logic 42 and in turn generates a CLKREAD signal. The CLKREAD signal serves as the read clock signal that drives the clock tree 16. The ENDP signal enables and disables the clock buffer, generating the CLKREAD signal when enabled. The CLKREAD signal drives clock tree 16 for the read data only during a read operation so that less power is consumed by clock tree 16 than would be when differential clock signals VCLK and VbCLK are coupled directly to, and drive, clock tree 16.

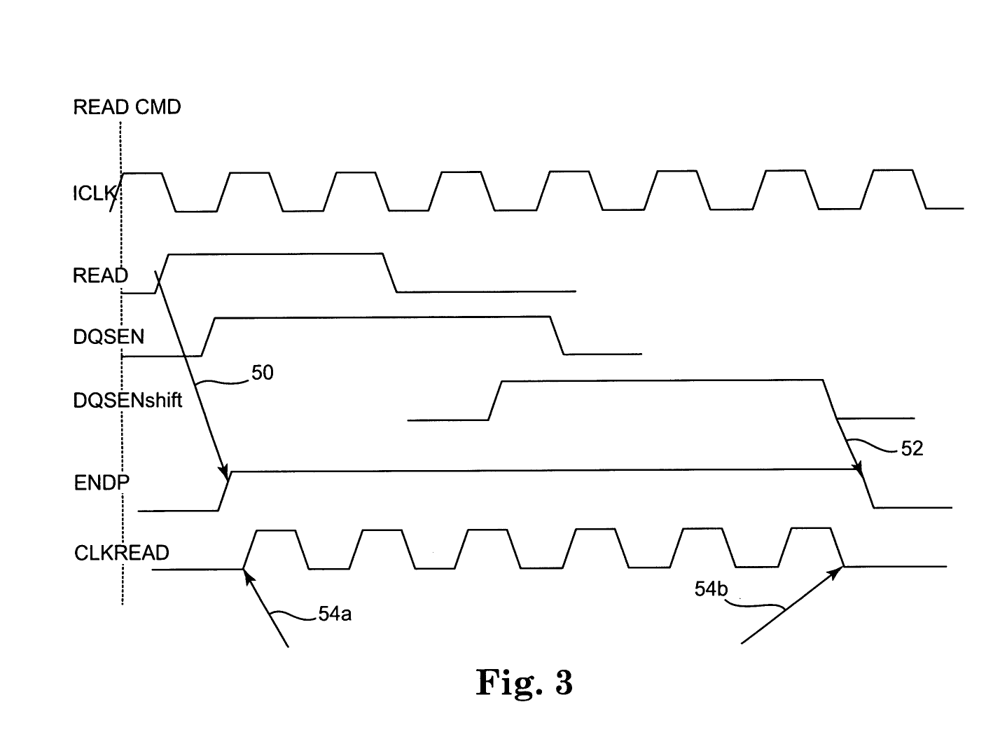

In order to further illustrate the embodiment of FIG. 2, some of the timing signals for the embodiment are illustrated in the timing diagram of FIG. 3. Illustrated are the ICLK signal, the READ signal, a DQSEN signal, the DQSENshift signal, the ENDP signal and the CLKREAD signal.

In FIG. 3, a read command is asserted at the front end (dotted vertical line) of the illustrated timing signals. As such, the BANKACTIVE signal, indicating that a memory bank is to be accessed, goes high. In this way, data clock receiver 40 is enabled as soon as a bank is activated, thereby driving the internal clock ICLK that is used by the buffer enable logic 42 and clock buffer 44.

The internal READ command signal and the DQSEN signal are active high while a read operation is ongoing. The DQSENshift signal is generated from the DQSEN signal and shifted by a number of clock cycles. This shifted signal allows for latencies during the read cycle. When the internal READ command signal goes high, this causes the ENDP signal to go high (illustrated by arrow 50 in FIG. 3), thereby enabling clock buffer 44.

The low-going transition of DQSEN signal indicates the when the read burst is completed. The clock buffer 44 is not disabled with the low-going transition of DQSEN signal, however. Instead, it is the low-going transition of the DQSENshift signal that disables clock buffer 44, as illustrated with arrow 52 in FIG. 3.

As such, the CLKREAD signal is only active while the ENDP signal is active high during a read burst operation. This active period is defined between the high-going transition of the DQSEN signal until the low-going transition of the DQSENshift signal (illustrated between the arrows 54a and 54b in FIG. 3). In this way, after the read burst operation, the CLKREAD signal is forced low to reduce power consumption by clock tree 16.

As is evident from timing signals in FIG. 3, the ICLK data clock receiver 40 is generated once the BANKACTIVE signal goes active when memory chip 10 is active. As such, a certain amount of power is consumed in running clock receiver 40, buffer enable logic 42, and clock buffer 44. The amount of power consumed, however, is less than the amount of power consumed by running clock tree 16 for the entire time that memory chip 10 is active.

For example, in situations where the differential clock signals VCLK and VbCLK directly drive clock tree 16, once the BANKACTIVE signal goes active when memory chip 10 is active, clock tree 16 is constantly driven and consumes significant power. By inserting clock control circuit 35 on memory device 10, the driving of clock tree 16 can be interrupted outside of a read operation even when memory chip 10 is active. Interrupting clock tree 16 saves significant power, which can be especially significant in low power applications.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory component configured in a semiconductor wafer, the memory component comprising:
at least one memory bank array out of which data is read during a read operation;
a first and a second region;
a clock tree coupled between the first and second regions for driving data during the read operation; and
a clock control circuit within one of the first and second regions that is responsive to read control signals in order to prevent driving the clock tree outside of the read operation.

2. The memory component of claim 1, further comprising:
a plurality of data pads and off-chip drivers within the first region;
a plurality of command and address pads within the second region; and
a data path coupled to the memory bank array and to the data pads;
wherein the data pads, off-chip drivers, command and address pads, and data path cooperate to bus data from the memory bank array during the read operation.

3. The memory component of claim 2, wherein the first region is located adjacent a first edge of the wafer and wherein the second region is located adjacent a second edge of the wafer opposite the first.

4. The memory component of claim 3, wherein the clock control circuit receives a clock signal from off the semiconductor wafer and regulates the clock signal in accordance with the read control signals in order to prevent driving the clock tree outside of the read operation.

5. The memory component of claim 1; wherein the memory component is configured as a low power DRAM chip.

6. A memory component configured to clock out data during a read operation, the memory component comprising:
a plurality of memory bank arrays;
a plurality of data pads and off-chip drivers within a first region of the memory component;
a plurality of command and address pads within a second region of the memory component;
a clock tree coupled between the first and second regions for clocking the data pads and off-chip drivers during the read operation; and
a clock control circuit within the second region that is responsive to read control signals and that disables the clock tree outside of the read operation.

7. The memory component of claim 6, wherein the clock control circuit further comprises:
a clock receiver configured to receive a first clock signal from off the memory component and to generate a second clock signal;
buffer enable logic configured to receive the second clock signal and to generate an enable signal; and
a clock buffer configured to receive the second clock signal and the enable signal and to generate a third clock signal.

8. The memory component of claim 7, wherein the third clock signal drives the clock tree such that clock tree is active only during the read operation.

9. The memory component of claim 8, wherein the clock receiver is further configured to receive a bankactive signal indicative of when a memory bank array is selected for a read operation and wherein the buffer enable logic is further configured to receive a read signal indicative of when a read operation has begun.

10. The memory component of claim 6, wherein the first region is located adjacent a first edge of the memory component and wherein the second region is located adjacent a second edge of the memory component opposite the first.

11. A memory component comprising:
at least one memory bank array out of which data is read during a read operation;
a plurality of data pads and off-chip drivers within a first region of the memory component;
a plurality of command and address pads within a second region of the memory component;
a clock tree coupled between the first and second regions for driving data during the read operation; and
means for prevent driving the clock tree outside of the read operation.

12. The memory component of claim 11, further comprising a clock circuit configured to receive read control signals and clock signal from off the memory component in order to prevent driving the clock tree outside of the read operation.

13. The memory component of claim 11, wherein the first region and second regions are separated such that the clock tree between them has significant length.

14. A method for reading from a memory component, the method comprising:
reading from at least one memory bank array during a read operation;
providing a plurality of data pads and off-chip drivers within a first region of the memory component;
clocking the plurality of data pads and off-chip drivers with a clock tree during the read operation, the clock tree coupled to the first region; and
disabling the clock tree outside the read operation with a clock control circuit, the clock control circuit provided within a second region.

15. The method of claim 14, further comprising providing a clock receiver that is configured to receive a first clock signal from off the memory component and to generate a second clock signal.

16. The method of claim 16, further comprising providing buffer enable logic configured to receive the second clock signal and to generate an enable signal.

17. The method of claim 16, further comprising providing a clock buffer configured to receive the second clock signal and the enable signal and to generate a third clock signal, wherein the third clock signal drives the clock tree such that clock tree is active only during the read operation.

18. The method of claim 17, further wherein the clock receiver is further configured to receive a bankactive signal indicative of when a memory bank array is selected for a read operation and wherein the buffer enable logic is further configured to receive a read signal indicative of when a read operation has begun.

19. A method of reading from a semiconductor memory, the method comprising:
providing a plurality of data pads and off-chip drivers within a first region of the semiconductor memory;
providing a clock receiver, buffer enable logic, and a clock buffer within a second region of the semiconductor memory;
providing a first clock signal from off the semiconductor memory to the clock receiver such that the clock receiver generates a second clock signal;
providing the second clock signal to the buffer enable logic such that the buffer enable logic generates an enable signal;
providing the second clock signal and the enable signal to the clock buffer such that the clock buffer generates a third clock signal;
providing the third clock to a clock tree; and
clocking the plurality of data pads and off-chip drivers with the clock tree only during the read operation.

20. The method of claim 19, wherein the clock tree is coupled between the first and second regions such that it has significant length.
